(19) United States
(12) Patent Application Publication
(10) Pub. No.: US 2019/0131481 A1
(43) Pub. Date: May 2, 2019

(54) ENCAPSULATION COVER FOR AN ELECTRONIC PACKAGE

(71) Applicant: STMicroelectronics (Grenoble 2) SAS, Grenoble (FR)

(72) Inventors: Marie-Astrid PIN, La Murette (FR); Jegger PADERNILLA, Calamba (PH); Jean-Michel RIVIERE, Froges (FR)

(73) Assignee: STMicroelectronics (Grenoble 2) SAS, Grenoble (FR)

(21) Appl. No.: 16/177,667

(22) Filed: Nov. 1, 2018

(30) Foreign Application Priority Data
Nov. 2, 2017 (FR) 1760336

(51) Int. Cl. H01L 31/16

(52) U.S. Cl. CPC H01L 31/16; G01V 8/10

(57) ABSTRACT

An encapsulation cover for an electronic package is formed by a first cover body and a second cover body. The first and second cover bodies are assembled together by a bonding material. Frontal walls of the first and second cover bodies are superposed and include through-passages that facing one another and are provided with optical elements allowing light to pass through. At least one surface of the frontal walls of the first and second cover bodies includes void containing the bonding material.

### PRIORITY CLAIM

This application claims the priority benefit of French Application for Patent No. 1760336, filed on Nov. 2, 2017, the content of which is hereby incorporated by reference in its entirety to the maximum extent allowable by law.

### TECHNICAL FIELD

Embodiments relate to the field of packages, in particular to those which are intended to contain electronic chips including light radiation emitters and/or light radiation sensors, which may colloquially be referred to as “electronic packages”.

### BACKGROUND

It is known practice to produce electronic packages that comprise electronic chips mounted on substrate wafers and encapsulation covers for the chips, which covers are mounted on the substrate wafers. These encapsulation covers comprise prefabricated cover bodies that have through-passages and shoulders around these passages and are provided with optical elements allowing light to pass through, which are generally made of glass and are added to the shoulders and attached by means of layers of adhesive.

### SUMMARY

According to one embodiment, an encapsulation cover for an electronic package is provided, which cover comprises a first cover body and a second cover body, which are assembled together by means of a bonding material, these cover bodies comprising respective superposed frontal walls that have through-passages that are located facing one another and are provided with optical elements allowing light to pass through.

The bonding material may be located between the frontal walls of the first and second cover bodies.

At least one of the frontal walls has at least one void facing the other frontal wall and containing bonding material.

Said void may comprise at least one groove made in at least one of the frontal walls, facing the other frontal wall, this groove surrounding, at a distance, at least one through-passage and containing bonding material.

At least one of the optical elements may be added to the corresponding cover body.

At least one of the optical elements may be inserted into the corresponding cover body by overmolding the latter around this optical element.

The first cover body may comprise a peripheral wall that protrudes with respect to its frontal wall, unlike the frontal wall of the second cover body.

The first cover body may comprise an inner wall that protrudes with respect to its frontal wall unlike the frontal wall of the second cover body, delimiting two cavities, the frontal walls of the first and second cover bodies having through-passages that are provided with optical elements facing said cavities.

An electronic package is also provided, which package comprises a substrate wafer, at least one electronic component including at least one optical sensor and/or one optical emitter, mounted on top of a face of the substrate wafer, and an encapsulation cover such as defined above, mounted on said face of the substrate wafer so as to form a chamber in which the electronic component is located, the frontal walls of the cover bodies being in front of the electronic component.

The electronic component may pass through an inner wall of the encapsulation cover.

An electronic package is also provided, which package comprises a substrate wafer, at least two electronic components including at least one optical sensor and/or one optical emitter, mounted on top of a face of the substrate wafer, and an encapsulation cover such as defined above, mounted on said face of the substrate wafer so as to form two cavities in which the electronic components are located, the frontal walls of the cover bodies being in front of the electronic components and having through-openings that are provided with optical elements allowing light to pass through between the cavities and the exterior, respectively.

### BRIEF DESCRIPTION OF THE DRAWINGS

Electronic packages comprising encapsulation covers and modes of fabrication will now be described by way of exemplary embodiments illustrated by the appended drawing, in which:

FIG. 1 shows a cross section of an electronic package, along I-I of FIG. 2;

FIG. 2 shows a horizontal cross section of the electronic package of FIG. 1, along II-II of FIG. 1;

FIG. 3 shows a cross section of the electronic package of FIG. 1, along III-III of FIG. 2;

FIG. 4 shows a horizontal cross section between two frontal walls of an encapsulation cover for the electronic package of FIG. 1; and

FIG. 5 shows a horizontal cross section between two frontal walls of a variant embodiment of an encapsulation cover for the electronic package.

### DETAILED DESCRIPTION

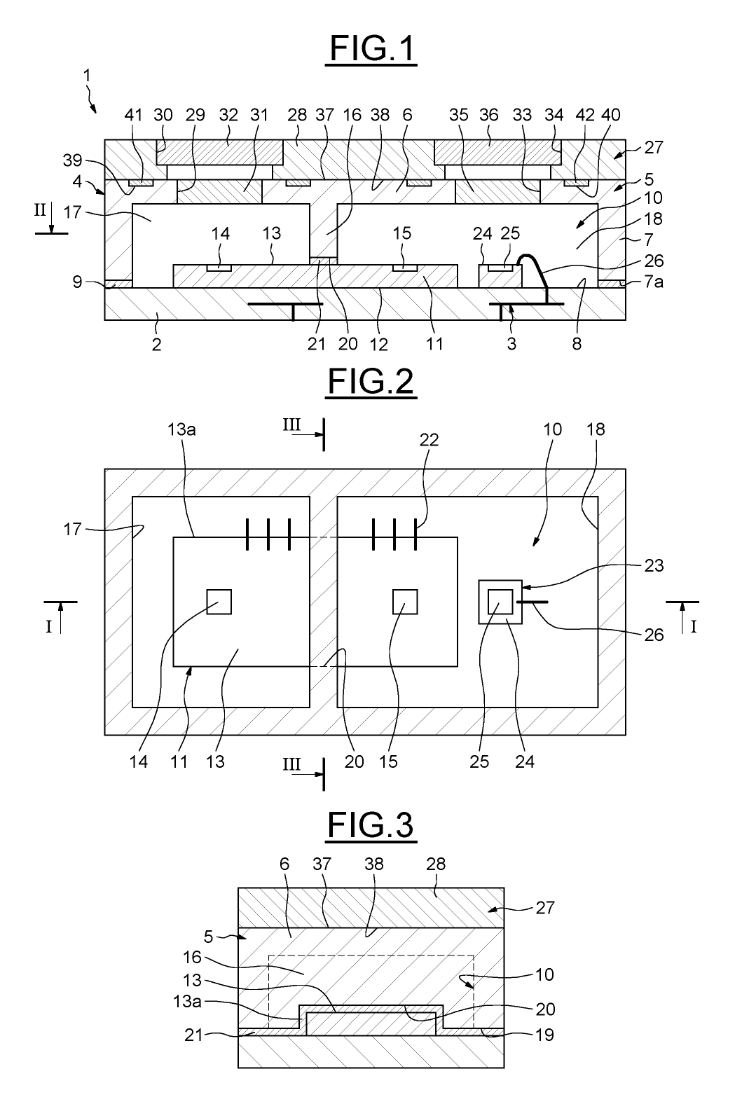

FIGS. 1 to 3 illustrate an electronic package 1 that comprises a substrate wafer 2 including a network of electrical connections 3, from one face of this wafer to the other, and an encapsulation cover 4 that comprises a first cover body 5 that comprises a front or frontal wall 6 that is parallel to the substrate wafer 2 and a peripheral wall 7 that extends backwards, a back end edge 7a of which is attached to a peripheral zone of a front face 8 of the substrate wafer 2 by means of a bead of adhesive 9, so as to delimit a chamber 10.

The electronic package 1 comprises an electronic chip 11 that is installed in the chamber 10 and has a back face 12 that is bonded to the front face 8 of the substrate wafer 2, the encapsulation cover 4 being at a distance from the chip 11, the front wall 6 being in front of the electronic chip 11.

According to the example shown, the chip 11 comprises, in its front face 13, two optical sensors 14 and 15 that are longitudinally remote from one another.

The first cover body 5 of the encapsulation cover 4 comprises a transverse inner separating partition 16 that protrudes from the frontal wall 5 and joins two opposite sides of the peripheral wall 6.

The inner separating partition 16 divides the chamber 10 into two cavities 17 and 18 and straddles the chip 11 at a site such that the sensors 14 and 15 are located on either side and are at a distance from the inner separating partition 16, inside the cavities 17 and 18.

The inner separating partition 16 has a back edge 19 that is provided with a notch 20 through which the chip 11 passes. A bead of adhesive 21 is interposed between the back edge 19 and the zones of the front face 8 of the substrate wafer 2 that are located on either side of the chip 11 and between the notch 20 and zones of the front face 13 and flanks 13a of the chip 11.

The chip 11 is linked to a network of electrical connections 3 of the substrate wafer 2 by means of electrical wires 22.

An electronic chip 23 that is bonded to the front face 108 of the substrate wafer 2, beside the chip 11, is installed inside the cavity 18. The chip 23 comprises, in its front face 24, a light radiation emitter 25 and it is linked to the network of electrical connections 3 by electrical wires 26.

The encapsulation cover 4 additionally comprises a second cover body 27 comprising a frontal wall 28 that is superposed over the frontal wall 6 of the cover body 5 and is in front of the latter. For example, the frontal wall 28 covers the frontal wall 6.

The frontal wall 6 of the first cover body 5 and the frontal wall 28 of the second cover body 27 have respective through-openings 29 and 30 that are located facing one another and are provided with respective optical elements 31 and 32, allowing light to pass between the cavity 17 and the exterior.

The frontal wall 6 of the first cover body 5 and the frontal wall 28 of the second cover body 27 have respective through-openings 33 and 34 that are located facing one another and are provided with respective optical elements 35 and 36, allowing light to pass between the cavity 18 and the exterior.

The first cover body 4 and the second cover body 27 are assembled together by means of a bonding material that is located away from the through-passages 29, 30, 33 and 35.

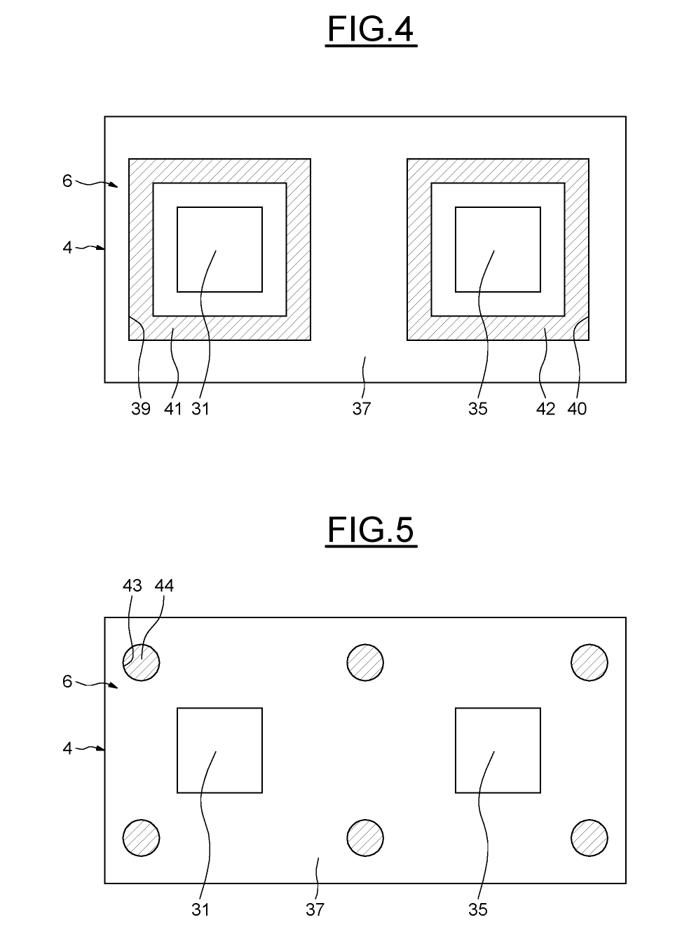

As illustrated in FIGS. 1, 3 and 4, the front face 37 of the frontal wall 6, which faces the back face 38 of the frontal wall 28, comprises voids that take the form of annular grooves 39 and 40 surrounding, at a distance, the through-openings 29 and 33 and that contain bonding material, so as to form annular bonding beads 41 and 42 that are interposed between the frontal wall 6 and the frontal wall 28. The front face 37 of the frontal wall 6 and the back face 38 of the frontal wall 28 may make contact with one another or be a short distance from one another.

Similarly, the back face 38 of the frontal wall 28 may comprise annular grooves that are located around and at a distance from the through-passages 30 and 34 and that contain bonding material for forming annular bonding beads.

For example, annular grooves may be formed both in the front face 37 of the frontal wall 6 and in the back face 38 of the frontal wall 28 and facing one another, so as to form annular beads that are equivalent to the annular beads 41 and 42.

The substrate wafer 2, the first and second cover bodies 5 and 28 of the encapsulation cover 4, the bead of adhesive 9, the bead of adhesive 20 and the beads of bonding material 41 and 42 are made of opaque materials.

The electronic package 1 may operate in the following way.

The emitter 25 of the chip 11 emits light, for example infrared, radiation outwards through the optical elements 35 and 36. This light radiation present in the cavity 18 is detected by the sensor 15 of the chip 11. The sensor 14 of the chip 11 detects external light radiation through the optical elements 31 and 32.

The optical elements 31, 32, 35 and 36 may be made of glass and any of them may by treated so as to form lenses and/or light filters. For example, the optical elements 31 and/or 32 may be treated so as to form an infrared filter and an optical lens for focusing light towards the sensor 14.

Advantageously, the electronic package 1 may constitute a means for detecting the proximity of a body in front of the encapsulation cover 4 by processing the signals arising from the sensors 14 and 15.

According to one variant embodiment illustrated in FIG. 5, the face 37 of the frontal wall 6 of the cover body 5 has distributed holes 43 that contain bonding material, forming adhesive points 44 between the cover body 5 and the cover body 27. In this case, the faces 37 and 38 of the cover bodies 5 and 27 make contact so as to avoid light from the exterior entering into the cavities 17 and 18. Similarly or alternatively, corresponding holes containing bonding material may be made in the face 38 of the cover body 27.

According to one variant embodiment, at least some of the optical elements 31, 32, 35 and 36 may be added to the cover bodies 5 and 27, respectively. For example, at least some of the optical elements 31, 32, 35 and 36 may be mounted by bonding, by potentially being fitted within the corresponding through-passages 39, 30, 33 and 34, or they may be force-fitted into the corresponding through-passages 39, 30, 33 and 34, the through-passages 39, 30, 33 and 34 having annular bearing shoulders.

According to another variant embodiment, at least some of the optical elements 31, 32, 35 and 36 may be inserted into the cover bodies 5 and 27, by overmolding the material of the cover bodies 5 and 27 around the optical elements 31, 32, 35 and 36, respectively.

According to one variant embodiment, the cover bodies 5 and 27 may take shapes suitable for positioning with respect to one another, for example engaged with one another, so that the optical axes of the optical elements 31 and 35 of the cover body 5 and of the optical elements 32 and 36 of the cover body 27, respectively, coincide.

According to one variant embodiment of the electronic package 1, an equivalent electronic package comprises separate chips that are respectively entirely located within cavities delimited by an inner wall of an encapsulation cover that is equivalent to the encapsulation cover 4.

According to one variant embodiment of the electronic package 1, an equivalent electronic package comprises an encapsulation cover delimiting a single cavity within which at least one chip provided with a light radiation emitter or sensor is located, this encapsulation cover being provided with an optical element that is rigidly connected to the first cover body and with an element that is rigidly connected to the second cover body, allowing light to pass between this single cavity and the exterior.

1. An encapsulation cover for an electronic package, comprising:
a first cover body; and
a second cover body;
wherein the first and second cover bodies are assembled together by a bonding material;
the first cover body including a first frontal wall with a first face and the second cover body including a second frontal wall with a second face;
wherein the first and second frontal walls include through-passages that are located facing one another and are provided with optical elements allowing light to pass through; and
wherein at least one of the first face and the second face has at least one void facing the other of the first face and the second face, the at least one void containing the bonding material.

2. The cover according to claim 1, in which the bonding material is located between the first and second faces of the first and second frontal walls of the first and second cover bodies, respectively.

3. The cover according to claim 1, wherein the first and second faces of the first and second frontal walls are in contact with each other.

4. The cover according to claim 1, wherein said void comprises at least one groove made in said at least one of the first face and the second face, said groove surrounding, at a distance, at least one of said through-passages.

5. The cover according to claim 1, wherein at least one of the optical elements is added to the corresponding cover body.

6. The cover according to claim 1, wherein at least one of the optical elements is inserted into the corresponding cover body by overmolding the cover body around said at least one of the optical elements.

7. The cover according to claim 1, wherein the first cover body further comprises a peripheral wall that protrudes from a back face of the first frontal wall, and wherein the second cover body does not include a peripheral wall.

8. The cover according to claim 7, wherein the first cover body further comprises an inner wall that protrudes from the back face of the first frontal wall to delimiting with the peripheral wall a first cavity and a second cavity, the first frontal wall of the first cover body including first and second through-passages that are provided with optical elements facing said first and second cavities.

9. An electronic package, comprising:
a substrate wafer;
a first electronic component mounted on top of a face of the substrate wafer; and
an encapsulation cover mounted to the substrate wafer so as to form a chamber in which the electronic component is located, wherein the encapsulation cover comprises:
a first cover body; and
a second cover body;
wherein the first and second cover bodies are assembled together by a bonding material;
the first cover body including a first frontal wall with a first face and the second cover body including a second frontal wall with a second face;
wherein the first and second frontal walls include through-passages that are located facing one another and are provided with optical elements allowing light to pass through; and
wherein at least one of the first face and the second face has at least one void facing the other of the first face and the second face, the at least one void containing the bonding material.

10. The package according to claim 9, wherein the first electronic component includes at least one optical sensor.

11. The package according to claim 9, wherein the first electronic component includes an optical emitter.

12. The package according to claim 9, wherein the first electronic component passes through an inner wall of the first cover body of the encapsulation cover.

13. The package according to claim 9, in which the bonding material is located between the first and second faces of the first and second frontal walls of the first and second cover bodies, respectively.

14. The package according to claim 9, wherein the first and second faces of the first and second frontal walls are in contact with each other.

15. The package according to claim 9, wherein said void comprises at least one groove made in said at least one of the first face and the second face, said groove surrounding, at a distance, at least one of said through-passages.

16. The package according to claim 9, wherein at least one of the optical elements is added to the corresponding cover body.

17. The package according to claim 9, wherein at least one of the optical elements is inserted into the corresponding cover body by overmolding the cover body around said at least one of the optical elements.

18. The package according to claim 9, wherein the first cover body further comprises a peripheral wall that protrudes from a back face of the first frontal wall, and wherein the second cover body does not include a peripheral wall.

19. The package according to claim 18, wherein the first cover body further comprises an inner wall that protrudes from the back face of the first frontal wall to delimiting with the peripheral wall a first cavity and a second cavity, the first frontal wall of the first cover body including first and second through-passages that are provided with optical elements facing said first and second cavities.

20. The package according to claim 9, further comprising:
a second electronic component mounted on top of the face of the substrate wafer;
wherein the first cover body defines a first cavity and a second cavity, and where the first electronic component is located at least within the first cavity and the second electronic component is located only within the second cavity.
